(19) United States
(12) Patent Application Publication
(10) Pub. No.: US 2020/0198711 A1
(43) Pub. Date: Jun. 25, 2020

(54) PIEZOELECTRIC BELLOW CONFIGURED TO CONTROL DOWNFORCE

(71) Applicant: GM GLOBAL TECHNOLOGY OPERATIONS LLC, DETROIT, MI (US)

(72) Inventors: Taeyoung Han, Bloomfield Hills, MI (US); Bahram Khalighi, Birmingham, MI (US); Paul E. Krajewski, Troy, MI (US); Shailendra Kaushik, Novi, MI (US)

(21) Appl. No.: 16/227,177

(22) Filed: Dec. 20, 2018

(51) Int. Cl. B62D 35/02; B60T 1/16; B62D 37/02; B62D 35/00; H01L 41/04; H01L 41/09

(52) U.S. Cl. CPC B62D 35/02; B60T 1/16; B62D 37/02; B60Y 2300/045; H01L 41/042; H01L 41/0973; B60Y 2300/022; B62D 35/007

(57) ABSTRACT

An apparatus configured to control downforce is provided. The apparatus includes a piezoelectric bellow configured to generate airflow, a power controller configured to output a signal to actuate the piezoelectric bellow; and a controller configured to control the power controller based on vehicle dynamics information.

### INTRODUCTION

Apparatuses and methods consistent with exemplary embodiments relate to downforce control. More particularly, apparatuses and methods consistent with exemplary embodiments relate to piezoelectric bellows configured to adjust or generate downforce.

### SUMMARY

One or more exemplary embodiments provide a downforce control apparatus. More particularly, one or more exemplary embodiments provide an apparatus configured to control downforce through the operation of piezoelectric bellows.

According to an aspect of an exemplary embodiment, an apparatus configured to control downforce is provided. The apparatus includes a piezoelectric bellow configured to generate airflow, a power controller configured to output a signal to actuate the piezoelectric bellow; and a controller configured to control the power controller based on vehicle dynamics information.

The piezoelectric bellow may be disposed on one or more from among a bottom of an area under a front bumper of a vehicle and under a spoiler of a vehicle.

The piezoelectric bellow may include a plurality of piezoelectric bellows.

The piezoelectric bellow may include a top member, a bottom member and an inner member disposed in between the top and bottom members, the inner member may include a cavity and a nozzle, and the top and bottom members comprise a piezoelectric disc and a flexible diaphragm disposed around a circumferential axis of the piezoelectric disc.

The vehicle dynamics information may include one or more from among a yaw rate of a vehicle, a speed of a vehicle, a lateral acceleration of a vehicle, a deceleration of a vehicle, and a steering angle of a vehicle.

The power controller may be configured to adjust the power in range between 50 V and 200 V according to the vehicle dynamics information.

The apparatus may include a vehicle speed sensor configured to measure a speed of a vehicle, and the controller may be configured to control the power controller to actuate the piezoelectric bellow if the vehicle speed is greater than predetermined actuation speed.

The apparatus may include a vehicle stability sensor configured to measure at least one from among a yaw rate of a vehicle, a lateral acceleration of a vehicle, a deceleration of a vehicle, and a steering angle of a vehicle, and the controller is configured to control the power controller to actuate the piezoelectric bellow to assist in braking if the deceleration of the vehicle indicates a braking condition.

The controller may be configured to control the power controller to actuate the piezoelectric bellow to a power level corresponding to an amount of the deceleration.

The apparatus may include a vehicle stability sensor configured to measure at least one from among a yaw rate of a vehicle, a lateral acceleration of a vehicle, a deceleration of a vehicle, and a steering angle of a vehicle, and the controller may be configured to control the power controller to selectively actuate the piezoelectric bellow to assist in cornering if the lateral acceleration indicates a cornering condition.

The controller may be configured to control the power controller to actuate the piezoelectric bellow to a power level corresponding to an amount of the lateral acceleration.

The piezoelectric bellow may include a plurality of piezoelectric bellows disposed on a left bottom and right bottom of an area under a front bumper of the vehicle, and the controller may be configured to control the power controller to actuate the piezoelectric bellows disposed on the left bottom to the power level that generates a greater downforce than the piezoelectric bellows disposed on the right bottom if a left turn conditions is indicated by one or more from among the yaw rate of the vehicle, the speed of the vehicle, the lateral acceleration of the vehicle, and the steering angle of the vehicle.

The piezoelectric bellow may include a plurality of piezoelectric bellows disposed on a left bottom and right bottom of an area under a front bumper of the vehicle, and the controller may be configured to control the power controller to actuate the piezoelectric bellows disposed on the right bottom to the power level that generates a greater downforce than the piezoelectric bellows disposed on the left bottom if a right turn conditions is indicated by one or more from among the yaw rate of the vehicle, the speed of the vehicle, the lateral acceleration of the vehicle, and the steering angle of the vehicle.

The piezoelectric bellow may comprise a plurality of piezoelectric bellows disposed on a left bottom and right bottom of an area under a rear spoiler of the vehicle, and the controller may be configured to control the power controller to actuate the piezoelectric bellows disposed on the left bottom to the power level that generates a greater downforce than the piezoelectric bellows disposed on the right bottom if a left turn conditions is indicated by one or more from among the yaw rate of the vehicle, the speed of the vehicle, the lateral acceleration of the vehicle, and the steering angle of the vehicle.

The piezoelectric bellow may include a plurality of piezoelectric bellows disposed on a left bottom and right bottom of an area under a rear spoiler of the vehicle, and the controller may be configured to control the power controller to actuate the piezoelectric bellows disposed on the right bottom to the power level that generates a greater downforce than the piezoelectric bellows disposed on the left bottom if a right turn conditions is indicated by one or more from among the yaw rate of the vehicle, the speed of the vehicle, the lateral acceleration of the vehicle, and the steering angle of the vehicle.

The apparatus may further include a vehicle speed sensor configured to measure a speed of a vehicle. The controller may be configured to control the power controller to actuate the piezoelectric bellow to a constant power level if the vehicle speed indicates a constant speed condition.

According to an aspect of another exemplary embodiment, an apparatus configured to control downforce is provided. The apparatus includes a plurality of piezoelectric bellows disposed under a rear spoiler, the piezoelectric bellows configured to generate airflow, a power controller configured to output a signal to actuate the piezoelectric bellows, and a controller configured to control the power controller based on vehicle dynamics information including one or more from among a yaw rate of a vehicle, a speed of a vehicle, a lateral acceleration of a vehicle, a deceleration of a vehicle, and a steering angle of a vehicle.

The piezoelectric bellows may be further disposed in an area under a front bumper of a vehicle.

The apparatus may further include a vehicle speed sensor configured to measure the speed of a vehicle, and the controller may be configured to control the power controller to actuate the piezoelectric bellow if the vehicle speed is greater than predetermined actuation speed.

The controller may be further configured to control the power controller to actuate the piezoelectric bellow to a power level corresponding to an amount of the deceleration.

Other objects, advantages and novel features of the exemplary embodiments will become more apparent from the following detailed description of exemplary embodiments and the accompanying drawings.

### BRIEF DESCRIPTION OF THE DRAWINGS

The disclosed examples will hereinafter be described in conjunction with the following drawing figures, wherein like numerals denote like elements, and wherein:

FIG. 1 shows a block diagram of an apparatus configured to control downforce according to an exemplary embodiment;

FIG. 2 shows illustrations of various examples of downforce control by an apparatus configured to control downforce according several aspects of exemplary embodiments;

FIG. 3 shows a piezoelectric bellow of the apparatus configured to control downforce according to aspects of an exemplary embodiment; and

FIG. 4 shows a flow diagram of the apparatus configured to control downforce according to an aspect of an exemplary embodiment.

### DETAILED DESCRIPTION

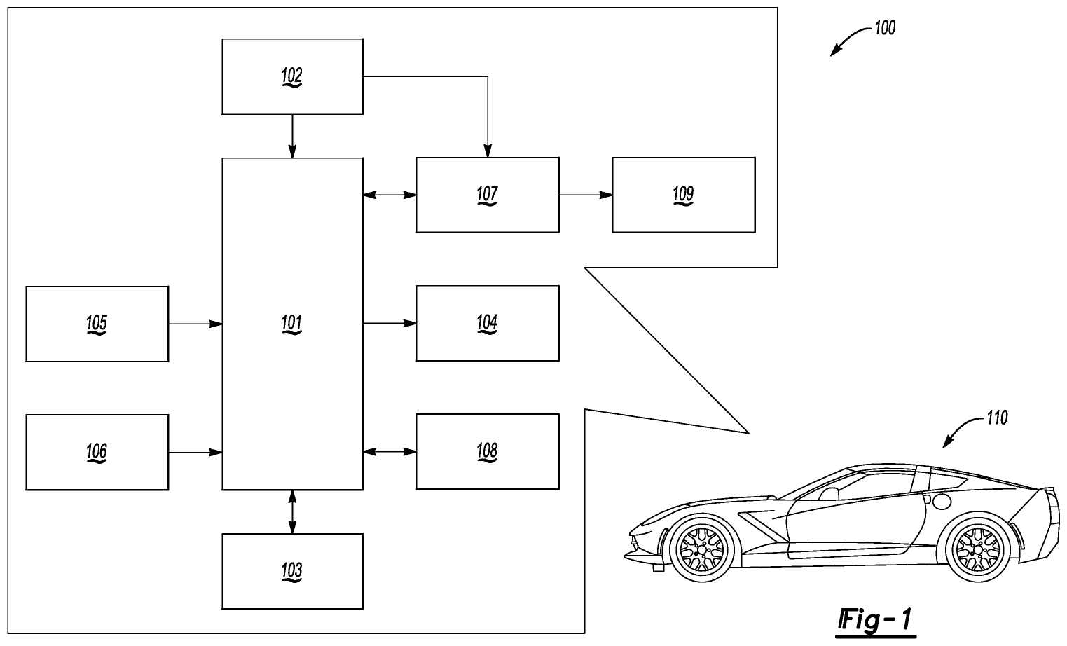

An apparatus configured to control downforce will now be described in detail with reference to FIGS. 1-4 of the accompanying drawings in which like reference numerals refer to like elements throughout.

The following disclosure will enable one skilled in the art to practice the inventive concept. However, the exemplary embodiments disclosed herein are merely exemplary and do not limit the inventive concept to exemplary embodiments described herein. Moreover, descriptions of features or aspects of each exemplary embodiment should typically be considered as available for aspects of other exemplary embodiments.

It is also understood that where it is stated herein that a first element is “connected to,” “attached to,” “formed on,” or “disposed on” a second element, the first element may be connected directly to, formed directly on or disposed directly on the second element or there may be intervening elements between the first element and the second element, unless it is stated that a first element is “directly” connected to, attached to, formed on, or disposed on the second element. In addition, if a first element is configured to “send” or “receive” information from a second element, the first element may send or receive the information directly to or from the second element, send or receive the information via a bus, send or receive the information via a network, or send or receive the information via intermediate elements, unless the first element is indicated to send or receive information “directly” to or from the second element.

Throughout the disclosure, one or more of the elements disclosed may be combined into a single device or into one or more devices. In addition, individual elements may be provided on separate devices.

Vehicle stability or traction are key issues in automobile design and engineering because they affect the experience of the driver and the occupant during various vehicle maneuvers including, for example, acceleration, braking, deceleration, and/or cornering. Vehicle stability or traction may depend on parameters or elements such as speed, body design, acceleration, steering angle, downforce, etc.

Downforce is one element that can be controlled or affected by various devices or accessories on a vehicle. In one example, airflow controls may be implemented by adding additional mechanical devices or electromechanical devices to the body of the vehicle to regulate or deflect airflow thereby increasing downforce on a part of the vehicle. One type of device that may be used to affect the airflow around a vehicle is a piezoelectric bellow. However, the piezoelectric bellow needs to be controlled according to vehicle dynamics information of the vehicle in order to increase stability or traction.

FIG. 1 shows a block diagram of an apparatus configured to control downforce 100 according to an exemplary embodiment. As shown in FIG. 1, the apparatus configured to control downforce 100, according to an exemplary embodiment, includes a controller 101, a power supply 102, a storage 103, an output 104, a sensor 105, a user input 106, a power controller 107, a communication device 108 and a piezoelectric bellow 109. However, the apparatus configured to control downforce 100 is not limited to the aforementioned configuration and may be configured to include additional elements and/or omit one or more of the aforementioned elements. The apparatus configured to control downforce 100 may be implemented as part of a vehicle, as a standalone component, as a hybrid between an on vehicle and off vehicle device, or in another computing device.

The controller 101 controls the overall operation and function of the apparatus configured to control downforce 100. The controller 101 may directly or indirectly control one or more of a power supply 102, a storage 103, an output 104, a sensor 105, a user input 106, a power controller 107, a communication device 108 and a piezoelectric bellow 109, of the apparatus configured to control downforce 100. The controller 101 may include one or more from among a processor, a microprocessor, a central processing unit (CPU), a graphics processor, Application Specific Integrated Circuits (ASICs), Field-Programmable Gate Arrays (FPGAs), state machines, circuitry, and a combination of hardware, software and firmware components.

The controller 101 is configured to send and/or receive information from one or more of the power supply 102, the storage 103, the output 104, the sensor 105, the user input 106, the power controller 107, the communication device 108 and the piezoelectric bellow 109 of the apparatus configured to control downforce 100. The information may be sent and received via a bus or network, or may be directly read or written to/from one or more of the power supply 102, the storage 103, the output 104, the sensor 105, the user input 106, the power controller 107, the communication device 108 and the piezoelectric bellow 109 of the apparatus configured to control downforce 100. Examples of suitable network connections include a controller area network (CAN), a media oriented system transfer (MOST), a local interconnection network (LIN), a local area network (LAN), wireless networks such as Bluetooth and 802.11, and other appropriate connections such as Ethernet.

The power supply 102 provides power to one or more of the storage 103, the output 104, the sensor 105, the user input 106, the power controller 107, the communication device 108 and the piezoelectric bellow 109, of the apparatus configured to control downforce 100. The power supply 102 may include one or more from among a battery, an outlet, a capacitor, a solar energy cell, a generator, a wind energy device, an alternator, etc.

The storage 103 is configured for storing information and retrieving information used by the apparatus configured to control downforce 100. The storage 103 may be controlled by the controller 101 to store and retrieve information received from one or more sensors 105 as well as computer or machine executable instructions to control the piezoelectric bellow 109. In one example. the storage 103 may be configured to store vehicle dynamics information. The vehicle dynamics information may include one or more from among a yaw rate of a vehicle, a speed of a vehicle, a lateral acceleration of a vehicle, a deceleration of a vehicle, and a steering angle of a vehicle.

The storage 103 may include one or more from among floppy diskettes, optical disks, CD-ROMs (Compact Disc-Read Only Memories), magneto-optical disks, ROMs (Read Only Memories), RAMs (Random Access Memories), EPROMs (Erasable Programmable Read Only Memories), EEPROMs (Electrically Erasable Programmable Read Only Memories), magnetic or optical cards, flash memory, cache memory, and other type of media/machine-readable medium suitable for storing machine-executable instructions.

The output 104 outputs information in one or more forms including: visual, audible and/or haptic form. The output 104 may be controlled by the controller 101 to provide outputs to the user of the apparatus configured to control downforce 100. The output 104 may include one or more from among a speaker, audio, a display, a centrally-located display, a head up display, a windshield display, a haptic feedback device, a vibration device, a tactile feedback device, a tap-feedback device, a holographic display, an instrument light, an indicator light, etc.

The output 104 may output notification including one or more from among an audible notification, a light notification, and a display notification. The notification may include information notifying of the activation or deactivation of the piezoelectric bellow 109 or the apparatus configured to control downforce 100. The notification may include information notifying of the activation or deactivation of downforce control in a specific location on a vehicle including the apparatus configured to control downforce 100. The output 104 may also display images and information provided by one or more sensors 105.

The sensor 105 may include one or more from among an inertial measurement unit, an accelerometer, a pressure sensor, a vehicle speed sensor, a speedometer and any other sensor suitable for detecting vehicle dynamics information, such as a yaw rate of a vehicle, a speed of a vehicle, a lateral acceleration of a vehicle, a deceleration of a vehicle, and/or a steering angle of a vehicle, of the apparatus configured to control downforce 100.

The user input 106 is configured to provide information and commands to the apparatus configured to control downforce 100. The user input 106 may be used to provide user inputs, etc., to the controller 101. The user input 106 may include one or more from among a touchscreen, a keyboard, a soft keypad, a button, a motion detector, a voice input detector, a microphone, a camera, a trackpad, a mouse, a touchpad, etc. The user input 106 may be configured to receive a user input to acknowledge or dismiss the notification output by the output 104. The user input 106 may also be configured to receive a user input to activate or deactivate the apparatus configured to control downforce 100.

The power controller 107 may include circuitry including a signal generator such as a pulse generator (e.g., a solid-state pulse generator) and an amplifier. In addition, the power controller may include a direct current to direct current convertor and pulse generator such as a solid-state pulse generator. According to one example, the power controller may include transformer configured to convert AC power supplied by the power supply to an AC voltage and frequency to operate the piezoelectric bellow. According to another example, the power controller may include a direct current (DC) to DC converter configured to covert the power supplied by the power supply to an appropriate voltage and frequency to operate the piezoelectric bellow. According to yet another example, the power controller may be configured to convert 12V direct court power supplied by the power supply 102 or other power supply to a power signal in the range of 50-200 V, 10-20 mA and/or 100-800 HZ.

The power controller may be configured to adjust the frequency of an output signal in a range between 100-800 HZ according to one or more from among a yaw rate of a vehicle, a speed of a vehicle, a lateral acceleration of a vehicle, a deceleration of a vehicle, and/or a steering angle of a vehicle.

The communication device 108 may be used by apparatus configured to control downforce 100 to communicate with several types of external apparatuses according to various communication methods. The communication device 108 may be used to send/receive various information such as information on operation mode of the vehicle and control information for operating the apparatus configured to control downforce 100 to/from the controller 101.

The communication device 108 may include various communication modules such as one or more from among a telematics unit, a broadcast receiving module, a near field communication (NFC) module, a GPS receiver, a wired communication module, or a wireless communication module. The broadcast receiving module may include a terrestrial broadcast receiving module including an antenna to receive a terrestrial broadcast signal, a demodulator, and an equalizer, etc. The NFC module is a module that communicates with an external apparatus located at a nearby distance according to an NFC method. The GPS receiver is a module that receives a GPS signal from a GPS satellite and detects a current location. The wired communication module may be a module that receives information over a wired network such as a local area network, a controller area network (CAN), or an external network. The wireless communication module is a module that is connected to an external network by using a wireless communication protocol such as IEEE 802.11 protocols, WiMAX, Wi-Fi or IEEE communication protocol and communicates with the external network. The wireless communication module may further include a mobile communication module that accesses a mobile communication network and performs communication according to various mobile communication standards such as 3rd generation (3G), 3^{rd} generation partnership project (3GPP), long-term evolution (LTE), Bluetooth, EVDO, CDMA, GPRS, EDGE or ZigBee.

The piezoelectric bellow 109 is an electrical device that generates airflow inhaling and injecting air through the use of piezoelectric materials or parts. In particular, piezoelectric bellow 109 works by applying an electrical signal to the piezoelectric parts, thereby causing suction of air followed by emission of air. The piezoelectric bellow 109 may generate airflow with a peak velocity of around 200 m/s and an average velocity of between 60-80 m/s.

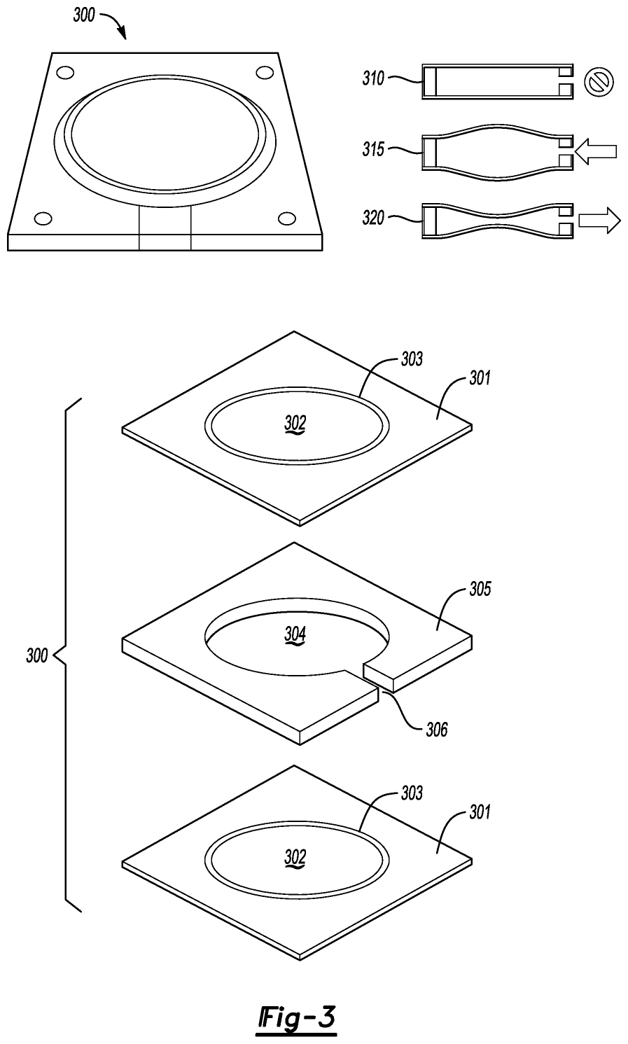

An exemplary embodiment of a piezoelectric bellow 109 of the apparatus configured to control downforce 100 is described in detail with respect to FIG. 3. While a dual piezoelectric disc configuration is shown in FIG. 3, a single piezoelectric disc configuration may be used. Moreover, the size of the cavity can be varied to achieve maximum/optimal air velocity.

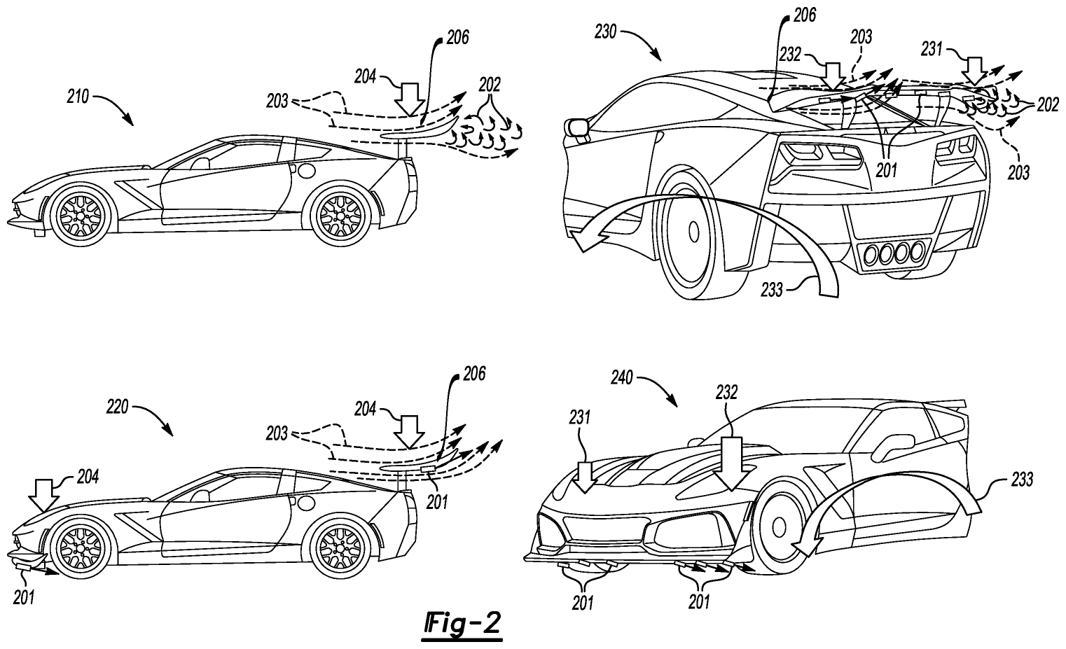

FIG. 2 shows illustrations of various examples of downforce control by an apparatus configured to control downforce 100 according several aspects of exemplary embodiments. Referring to FIG. 2, three example configurations of downforce control are shown. However, the exemplary embodiments are not limited to these examples and the apparatus configured to control downforce 100 may be used to control downforce in other scenarios or in other driving conditions.

In a first example, flow control is off as vehicle 210 moves in a forward direction. Airflow 203 may cause lift or a smaller downforce 204 at spoiler 206. On the other hand, vehicle 220 includes piezoelectric bellows 201 of the apparatus configured to control downforce 100 placed under the front of the vehicle 220 and under the spoiler 206 of the vehicle 220. When the piezoelectric bellows 201 are actuated, the downforce on the front of the vehicle and the rear of the vehicle, represented by arrows 204, is increased thereby increasing traction and stability.

In a second example, vehicle 230 includes piezoelectric bellows 201 under the rear spoiler 206 of vehicle 230 that are selectively actuated depending on the direction the vehicle is traveling. For example, if the vehicle 230 is cornering a left turn 233, the piezoelectric bellows 201 on the left side of spoiler 206 are actuated thereby increasing the downforce 232 on the left rear of the vehicle and assisting with the cornering or turning maneuver. On the other hand, the piezoelectric bellows 201 on the right side of spoiler 206 are not actuated or are actuated to emit a smaller jet flow than the piezoelectric bellows 201 on the left of the vehicle, thereby decreasing the downforce 231 on the right rear of the vehicle and further assisting with the cornering or turning maneuver. However, if the vehicle 230 was performing a right turn or right cornering maneuver, the actuation of the piezoelectric bellows 201 on the bottom of the front bumper would occur in the opposite manner to that described in the previous two sentences.

In a third example, vehicle 240 includes piezoelectric bellows 201 under the front bumper or front of vehicle 240 that are selectively actuated depending on the direction the vehicle is traveling. For example, if the vehicle 240 is cornering a left turn 233, the piezoelectric bellows 201 on the left side of the bottom of the front bumper are actuated thereby increasing the downforce 232 on the left front of the vehicle 240 and assisting with the cornering or turning maneuver. On the other hand, the piezoelectric bellows 201 on the right side of the bottom of the front bumper are not actuated or are actuated to emit a smaller jet flow than the piezoelectric bellows 201 on the left of the vehicle, thereby decreasing the downforce 231 on the right front of the vehicle and further assisting with the cornering or turning maneuver. However, if the vehicle 240 was performing a right turn or right cornering maneuver, the actuation of the piezoelectric bellows 201 on the bottom of the front bumper would occur in the opposite manner to that described in the previous two sentences.

FIG. 3 shows an example of a piezoelectric bellow 300 of the apparatus configured to control downforce 100 according to aspects of an exemplary embodiment. Referring to FIG. 3, a piezoelectric bellow 300 and its modes of operation are shown.

The piezoelectric bellow 300 may include a top member 301 (e.g., a first piezoelectric member), a bottom member 301 (e.g., a second piezoelectric member) and an inner member 305 (e.g., a spacer) disposed in between the top and bottom members.

The inner member may include a cavity 304 and a nozzle 306. The top and bottom members may each include piezoelectric discs 302 and flexible diaphragms 303 disposed around a circumferential axis of the piezoelectric discs 302. The piezoelectric discs 302 may be encircled by top and bottom members and the top and bottom members may be rigid members other than piezoelectric discs 302 or flexible diaphragms 303. The nozzle may be configured to suck or draw air into the cavity and then eject the air from the cavity as the first and second piezo electric discs are actuated.

Illustrations 310, 315, 320 show cutaway views of piezoelectric bellow 300 during modes of actuation. Specifically, illustration 310 shows an unactuated state of the piezoelectric bellow 300. Illustration 315 shows a first actuated state in where air is drawn or sucked through the nozzle 306 into the cavity 304. Finally, illustration 320 shows a second actuated state where air is ejected from the cavity 304 and blown or emitted by the nozzle 306.

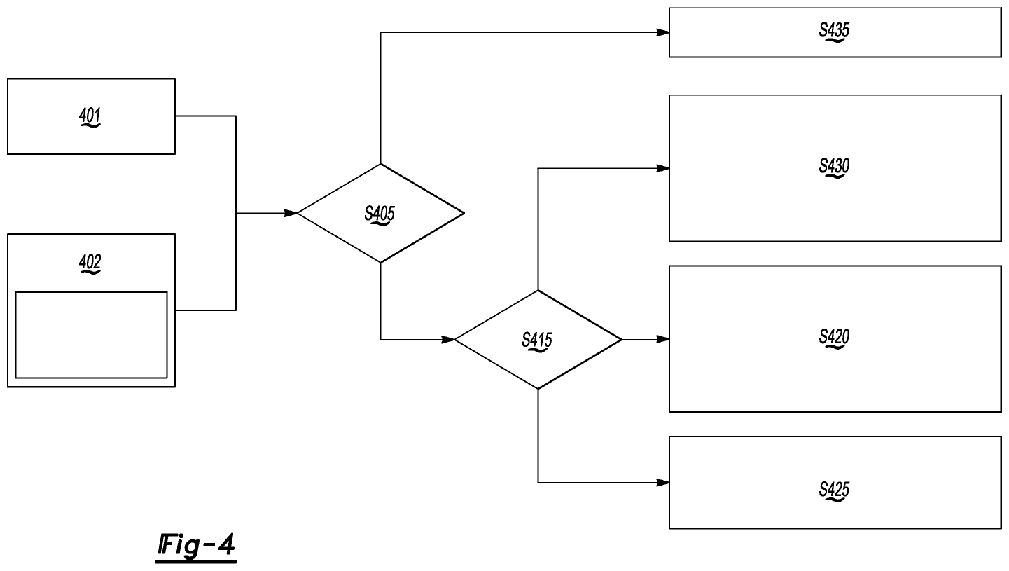

FIG. 4 shows a flow diagram of the apparatus configured to control downforce according to an aspect of an exemplary embodiment. Referring to FIG. 4, one or more pieces of vehicle dynamics information from among a vehicle speed information provided by a vehicle speed sensor 401, a yaw rate of a vehicle, a speed of a vehicle, a lateral acceleration of a vehicle, a deceleration of a vehicle, and/or a steering angle of a vehicle provided by a vehicle stability sensor 402 are provided.

In operation S405, it is determined whether the apparatus configured to control downforce is to be actuated based on the values of the vehicle dynamics information. For example, if vehicle speed information 401 indicates that the vehicle speed is less than a predetermined actuation speed (e.g., 30 mph), the apparatus configured to control downforce may be turned off in operation S435.

However, if the vehicle speed is greater than a predetermined actuation speed, it may be determined how to actuate the apparatus configured to control downforce or where traction force is demanded based on the vehicle dynamics information in operation S415. If a vehicle braking condition is detected from the vehicle dynamics information in operation S415, then the piezoelectric bellows on the vehicle, e.g., on the rear wing or spoiler, are actuated to maximize downforce or to a power level and/or frequency corresponding to rate of braking or deceleration in operation S430.

If a vehicle cornering or turning condition is detected from the vehicle dynamics information in operation S415, then the piezoelectric bellows on the side of the vehicle corresponding to the direction of the cornering or turning are actuated to a power level and/or frequency corresponding to the lateral acceleration from among the piezoelectric bellows on the vehicle, e.g., on the rear wing or spoiler and the piezoelectric bellows on the bottom front of the vehicle, in operation S420.

In one example, a left bank of piezoelectric bellows on the bottom front of the vehicle and on the bottom of the rear wing or spoiler are actuated to a power level greater than that of a right bank of piezoelectric bellows on the bottom front of the vehicle and on the bottom of the rear wing or spoiler during a left turn or cornering maneuver. In another example, a right bank of piezoelectric bellows on the bottom front of the vehicle and on the bottom of the rear wing or spoiler are actuated to a power level greater than that of a left bank of piezoelectric bellows on the bottom front of the vehicle and on the bottom of the rear wing or spoiler during a right turn or cornering maneuver.

If a max speed or steady speed condition is detected from the vehicle dynamics information in operation S415, then the piezoelectric bellows on the vehicle are turned off or set to low power setting to increase downforce as needed for traction control in operation S425.

The processes, methods, or algorithms disclosed herein can be deliverable to/implemented by a processing device, controller, or computer, which can include any existing programmable electronic control device or dedicated electronic control device. Similarly, the processes, methods, or algorithms can be stored as data and instructions executable by a controller or computer in many forms including, but not limited to, information permanently stored on non-writable storage media such as ROM devices and information alterably stored on writeable storage media such as floppy disks, magnetic tapes, CDs, RAM devices, and other magnetic and optical media. The processes, methods, or algorithms can also be implemented in a software executable object. Alternatively, the processes, methods, or algorithms can be embodied in whole or in part using suitable hardware components, such as Application Specific Integrated Circuits (ASICs), Field-Programmable Gate Arrays (FPGAs), state machines, controllers or other hardware components or devices, or a combination of hardware, software and firmware components.

One or more exemplary embodiments have been described above with reference to the drawings. The exemplary embodiments described above should be considered in a descriptive sense only and not for purposes of limitation. Moreover, the exemplary embodiments may be modified without departing from the spirit and scope of the inventive concept, which is defined by the following claims.

What is claimed is:

1. An apparatus configured to control downforce, the apparatus comprising:
a piezoelectric bellow configured to generate airflow;
a power controller configured to output a signal to actuate the piezoelectric bellow; and
a controller configured to control the power controller based on vehicle dynamics information.

2. The apparatus of claim 1, wherein the piezoelectric bellow is disposed on one or more from among a bottom of an area under a front bumper of a vehicle and under a spoiler of a vehicle.

3. The apparatus of claim 3, wherein the piezoelectric bellow comprises a plurality of piezoelectric bellows.

4. The apparatus of claim 1, wherein the piezoelectric bellow comprises a top member, a bottom member and an inner member disposed in between the top and bottom members,
wherein the inner member comprises a cavity and a nozzle, and
wherein the top and bottom members comprise a piezoelectric disc and a flexible diaphragm disposed around a circumferential axis of the piezoelectric disc.

5. The apparatus of claim 1, wherein the vehicle dynamics information comprises one or more from among a yaw rate of a vehicle, a speed of a vehicle, a lateral acceleration of a vehicle, a deceleration of a vehicle, and a steering angle of a vehicle.

6. The apparatus of claim 1, wherein the power controller is configured to adjust the power in range between 50 V and 200 V according to the vehicle dynamics information.

7. The apparatus of claim 1, further comprising a vehicle speed sensor configured to measure a speed of a vehicle,
wherein the controller is configured to control the power controller to actuate the piezoelectric bellow if the vehicle speed is greater than predetermined actuation speed.

8. The apparatus of claim 1, further comprising a vehicle stability sensor configured to measure at least one from among a yaw rate of a vehicle, a lateral acceleration of a vehicle, a deceleration of a vehicle, and a steering angle of a vehicle,
wherein the controller is configured to control the power controller to actuate the piezoelectric bellow to assist in braking if the deceleration of the vehicle indicates a braking condition.

9. The apparatus of claim 8, wherein the controller is configured to control the power controller to actuate the piezoelectric bellow to a power level corresponding to an amount of the deceleration.

10. The apparatus of claim 1, further comprising a vehicle stability sensor configured to measure at least one from among a yaw rate of a vehicle, a lateral acceleration of a vehicle, a deceleration of a vehicle, and a steering angle of a vehicle,
wherein the controller is configured to control the power controller to selectively actuate the piezoelectric bellow to assist in cornering if the lateral acceleration indicates a cornering condition.

11. The apparatus of claim 10, wherein the controller is configured to control the power controller to actuate the piezoelectric bellow to a power level corresponding to an amount of the lateral acceleration.

12. The apparatus of claim 11, wherein the piezoelectric bellow comprises a plurality of piezoelectric bellows disposed on a left bottom and right bottom of an area under a front bumper of the vehicle,
wherein the controller is configured to control the power controller to actuate the piezoelectric bellows disposed on the left bottom to the power level that generates a greater downforce than the piezoelectric bellows disposed on the right bottom if a left turn conditions is indicated by one or more from among the yaw rate of the vehicle, the speed of the vehicle, the lateral acceleration of the vehicle, and the steering angle of the vehicle.

13. The apparatus of claim 11, wherein the piezoelectric bellow comprises a plurality of piezoelectric bellows disposed on a left bottom and right bottom of an area under a front bumper of the vehicle,
wherein the controller is configured to control the power controller to actuate the piezoelectric bellows disposed on the right bottom to the power level that generates a greater downforce than the piezoelectric bellows disposed on the left bottom if a right turn conditions is indicated by one or more from among the yaw rate of the vehicle, the speed of the vehicle, the lateral acceleration of the vehicle, and the steering angle of the vehicle.

14. The apparatus of claim 11, wherein the piezoelectric bellow comprises a plurality of piezoelectric bellows disposed on a left bottom and right bottom of an area under a rear spoiler of the vehicle,
wherein the controller is configured to control the power controller to actuate the piezoelectric bellows disposed on the left bottom to the power level that generates a greater downforce than the piezoelectric bellows disposed on the right bottom if a left turn conditions is indicated by one or more from among the yaw rate of the vehicle, the speed of the vehicle, the lateral acceleration of the vehicle, and the steering angle of the vehicle.

15. The apparatus of claim 11, wherein the piezoelectric bellow comprises a plurality of piezoelectric bellows disposed on a left bottom and right bottom of an area under a rear spoiler of the vehicle,
wherein the controller is configured to control the power controller to actuate the piezoelectric bellows disposed on the right bottom to the power level that generates a greater downforce than the piezoelectric bellows disposed on the left bottom if a right turn conditions is indicated by one or more from among the yaw rate of the vehicle, the speed of the vehicle, the lateral acceleration of the vehicle, and the steering angle of the vehicle.

16. The apparatus of claim 1, further comprising a vehicle speed sensor configured to measure a speed of a vehicle,
wherein the controller is configured to control the power controller to actuate the piezoelectric bellow to a constant power level if the vehicle speed indicates a constant speed condition.

17. An apparatus configured to control downforce, the apparatus comprising:
a plurality of piezoelectric bellows disposed under a rear spoiler, the piezoelectric bellows configured to generate airflow;
a power controller configured to output a signal to actuate the piezoelectric bellows; and
a controller configured to control the power controller based on vehicle dynamics information including one or more from among a yaw rate of a vehicle, a speed of a vehicle, a lateral acceleration of a vehicle, a deceleration of a vehicle, and a steering angle of a vehicle.

18. The apparatus of claim 17, wherein the piezoelectric bellows are further disposed in an area under a front bumper of a vehicle.

19. The apparatus of claim 17, further comprising a vehicle speed sensor configured to measure the speed of a vehicle,
wherein the controller is configured to control the power controller to actuate the piezoelectric bellow if the vehicle speed is greater than predetermined actuation speed.

20. The apparatus of claim 17, wherein the controller is configured to control the power controller to actuate the piezoelectric bellow to a power level corresponding to an amount of the deceleration.
